(19) United States
(12) Patent Application Publication
(10) Pub. No.: US 2004/0197947 A1
(43) Pub. Date: Oct. 7, 2004

(54) Memory-cell filament electrodes and methods

(76) Inventors: Peter J. Fricke, Corvallis, OR (US); Warren B. Jackson, San Francisco, CA (US)

Correspondence Address: HEWLETT-PACKARD DEVELOPMENT COMPANY, Intellectual Property Administration, P.O. Box 272400, Fort Collins, CO, 80527-2400, US

(21) Appl. No.: 10/410,642

(22) Filed: Apr. 7, 2003

(51) Int. Cl. H01L 21/336

(52) U.S. Cl. 438/102

(57) ABSTRACT

A non-volatile memory cell of the type having a control element and a storage element has a storage element including a first material characterized by having a phase change in a predetermined temperature range, a second material having a negative differential resistance characteristic, the second material being in contact with the first material and being electrically coupled to the control element. The control element is operated to induce filamentary conduction through the second material such that the filamentary conduction causes the temperature of at least a portion of the first material to reach the predetermined temperature range, whereby a phase change occurs in at least a portion of the first material.

### TECHNICAL FIELD

This invention relates to phase-change memory cells and more particularly to filament electrodes for use in phase-change memory cells and methods for making and using such filament electrodes and memory cells.

### BACKGROUND

Phase-change memories have been known in the art for many years. Phase-change switching mechanisms require that a volume of material be heated in order that the structural phase of the material undergoes a change for storage of one binary bit of information. Associated with the change in phase is a change in electrical properties that forms the basis for retrieval of the information stored in the memory element. Various methods have been developed to minimize the volume or cross-section of the active region in which the phase is changed.

For example, tapered contacts or protruding electrodes having a conical or triangular cross-sectional shape forming an apex have been employed. Such electrodes are typically difficult to manufacture reproducibly with high yield for use in practical memory devices having many memory cells, especially if it is desired to fabricate a multi-layer memory structure.

### BRIEF DESCRIPTION OF THE DRAWINGS

The features and advantages of the disclosure will readily be appreciated by persons skilled in the art from the following detailed description when read in conjunction with the drawings, wherein:

FIG. 1 is a schematic diagram illustrating a first embodiment of a circuit for a memory-cell in accordance with the invention.

FIG. 2 is a schematic diagram illustrating a second embodiment of a circuit for a memory-cell in accordance with the invention.

FIGS. 3 and 4 are side-elevation cross-sectional views of a portion of a first embodiment of a memory made in accordance with the invention.

FIG. 5 is a flow chart illustrating an embodiment of a method for fabricating a memory in accordance with the invention.

FIG. 6 is a side-elevation cross-sectional view illustrating schematically a portion of a fourth embodiment of a memory made in accordance with the invention.

FIG. 7 is a schematic diagram of an equivalent circuit corresponding to the embodiment shown in FIG. 6.

FIGS. 8 and 9 are side-elevation cross-sectional views of a portion of a memory embodiment as illustrated schematically in FIG. 6.

For clarity of the description, the drawings are not drawn to a uniform scale. In particular, vertical and horizontal scales may differ from each other and may vary from one drawing to another.

### DETAILED DESCRIPTION OF EMBODIMENTS

Various embodiments of non-volatile memory cells made in accordance with the invention are described in detail below. Throughout this specification and the appended claims, the term “differential resistance” refers to the ratio of a small change in the voltage drop across a resistance to the change in current producing the voltage drop, i.e., the slope of the voltage-current characteristic for the material.

A non-volatile memory cell of the type having a control element and a storage element has a storage element including a first material characterized by having a phase change in a predetermined temperature range, and a second material having a negative differential resistance characteristic, the second material being in contact with the first material and being electrically coupled to the control element. The storage element of a memory cell is said to be programmed to store information in the cell when the phase of the first material is either changed or unchanged from its initial phase. The control element is operated to induce filamentary conduction through the second material such that the filamentary conduction causes the temperature of at least a portion of the first material to reach the predetermined temperature range, whereby a phase change occurs in at least a portion of the first material.

The energy and speed of a phase-change nonvolatile memory depends on the volume of material to be heated, the rate at which energy leaks away from that volume, and the rate at which energy is provided to the system. A small volume for the phase change is desirable, since a small volume, in comparison with a larger volume, lowers the energy required and/or increases the speed for altering the memory phase. It is difficult, however, to define volumes having lateral dimensions of 10 nm or less by using photolithography.

One aspect of the present invention is the use of current filamentation to create very small phase-change regions for non-volatile memory applications. While it is not intended to limit the invention to the consequences of any particular theory of operation, some characteristics of filamentary conduction are known and may contribute to operation of the embodiments described herein.

Filamentary conduction occurs in semiconductors when the conductivity exhibits a negative differential resistance (NDR). The NDR can be caused by various physical mechanisms. In a material having a positive thermal coefficient of conductivity, in which a current flow causes heating and the heating causes additional current to flow, the positive thermal coefficient leads to filamentary conduction. Impact ionization, carrier induced defect generation, and avalanche injection are additional methods that lead to NDR and therefore to filamentary conduction. Charge-enhanced tunneling is another way in which NDR can be created. Materials and structures that exhibit filamentary conduction include Si, SiGe and GaAs pin diodes, metal/amorphous-silicon junctions, tunneling insulators such as SiO₂ and Al₂O₃, and various other known semiconductors and structures made with them. By using any of these materials or structures, one can create a very small current filament with lateral dimensions on the order of ten nanometers or less.

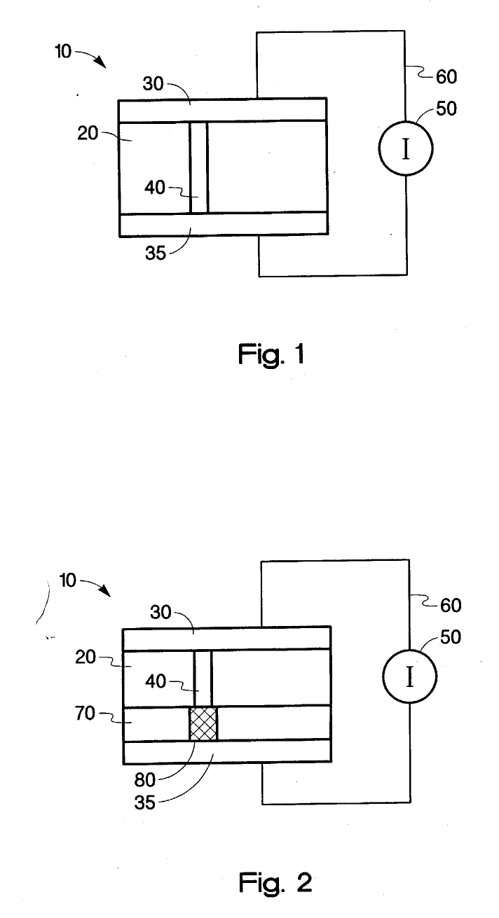

The temperature in such a filament is typically substantially higher than in the surrounding material. If the surrounding material has a low conductivity, then the energy to create such a filament will be small. The high temperature in the filament can cause a phase change of the material within the filament region and thus can result in a non-volatile change in the electrical characteristics of the material. This situation is illustrated schematically by the structure 10 in FIG. 1, in which a phase-change material 20 is in contact with conductive electrodes 30 and 35. A filament 40 is formed in the phase-change material 20 when a current (I) supplied from voltage source 50 is applied through connections 60.

Alternatively, as illustrated schematically in FIG. 2, heat from the filament region 40 can induce a phase change in a small region 80 of an adjoining medium 70 or the filament region 40 can focus the current to flow in a small region 80 of an adjoining medium 70. In the latter case, the heat generation is confined to the region of high current within the medium 70. In a practical memory device, the size of the electrodes 30 and 35 is typically defined photolithographically and is limited by the resolution of the photolithographic method employed in fabrication of the memory. In the cases illustrated by both FIGS. 1 and 2, the size of filament 40 is much smaller than the size of the photolithographically defined electrodes 30 and 35. Some advantages of the first structure (FIG. 1) are simplicity of fabrication, lower power, and increased speed. An advantage of the second structure (FIG. 2) is that the properties of the phase-change material can be selected independently from the properties of the filamentary conduction material, thus yielding a large set of materials available for operable systems. If the same material is chosen for both the phase-change material and the filamentary conduction material, then the structure of FIG. 2 becomes functionally equivalent to the structure of FIG. 1.

A filament 40 can interact with the phase-change material 20 in at least two ways. In the first type of interaction, current in the filament generates a hot region and the heat diffuses from the hot region into the phase-change material. The electrical properties of the phase-change material are thereby changed locally within a heat diffusion distance. This case requires effective thermal contact between the phase-change material and the filament-forming material. The size of the phase-change region and the speed of change depend on the spreading of heat as it moves from the filament region into the phase-change material. In a second type of interaction, the filament injects current into the phase-change material, which is much more resistive than the conductive filament. Because of the small injection site, the electrical energy deposition is confined to a region roughly the size of the filament rather than the device size. Moreover, processes such as avalanche injection or impact ionization can occur within the phase-change material to cause changes in the electrical properties of the phase change layer. In this case the speed depends only on the rate at which the electrical energy within the phase-change material is converted to heat, and the size of the region depends on how far the heat diffuses within the phase-change material. The second mechanism of interaction has potential advantages of higher speed, smaller phase-change regions, and reduced energy requirement.

Thus, the invention provides a new method for programming a non-volatile memory cell of the type having a control element and a storage element. In practicing the new method, one provides a storage element including a first material characterized by having a phase change in a predetermined temperature range, and one provides a second material having a negative differential resistance characteristic in contact with the first material and couples it electrically to the control element. One controls the control element to induce filamentary conduction through the second material such that the filamentary conduction causes the temperature of at least a portion of the first material to reach the predetermined temperature range, whereby a phase change occurs in at least said portion of the first material. As mentioned above, for some applications the first and second materials can be the same material, i.e., they can be identical. The two materials can also be different materials. Even if the two materials are not identical, they can be co-extensive in at least one direction (e.g., in the lateral direction as shown in FIG. 2). As shown in both FIGS. 1 and 2, the method may be implemented by electrically connecting the first material and second material in series.

The first (phase-change) material may comprise a chalcogenide or a semiconductor such as silicon, germanium, gallium arsenide, gallium nitride, or alloys, compounds, combinations, or mixtures of these substances. The second (filamentary conduction) material may comprise a material that exhibits a positive thermal coefficient of resistance, and it also may be a chalcogenide or a semiconductor such as silicon, germanium, gallium arsenide, gallium nitride, an insulator such as silicon nitride, silicon dioxide, or aluminum oxide (before filamentary conduction is induced), or alloys, compounds, combinations, or mixtures of these substances.

As mentioned above, the filamentary conduction can occur in a region of the second material having a lateral dimension of less than about ten nanometers. Thus, the cross-sectional area of the region of filamentary conduction in the second material can be less than about eighty square nanometers. These same size characteristics (i.e., having a lateral dimension of less than about ten nanometers and having a cross-sectional area of the region of filamentary conduction of less than about eighty square nanometers) may be achieved when the filamentary conduction occurs in the first material, which then is performing both as a phase-change material and as a filamentary conduction material. The filamentary conduction can be induced by utilizing the known phenomena of impact ionization, avalanche injection, charge-induced defect creation, or charge-enhanced tunneling.

Control elements are controlled using a control element electrode, which has an area that is typically defined photolithographically. The portion of the second (filamentary conduction) material in which filamentary conduction occurs has a cross-sectional area of less than the area of the control element electrode. The storage element has a storage element electrode having an area that may differ from that of the control element electrode. The filamentary conduction can occur in a region of the second material having a cross-sectional area of less than the storage element electrode area and can be limited to a minor fraction of the storage element electrode area or even to less than one-hundredth of the storage element electrode area.

The phase change occurs in a region that is at least partly determined by the size of the filamentary conduction region, which may be thought of as a filament electrode. As a result, the phase-change region is correspondingly very small. Thus, the portion of the phase-change material in which the phase change occurs has a cross-sectional area of less than the area of the control element electrode and can be limited to a minor fraction of the control element electrode area, or even to less than one-hundredth of the control element electrode area. Similarly, each storage element has a storage element electrode with a storage-element-electrode area, and the portion of the phase-change material in which the phase change occurs has a cross-sectional area of less than the storage-element-electrode area. Again, the portion in which the phase change occurs has a cross-sectional area that is a minor fraction of the storage-element-electrode area and may be limited to less than about one-hundredth of the storage-element-electrode area.

In the method illustrated by FIG. 2 for programming a non-volatile memory cell of the type having a control element and a storage element, one provides a storage element including a first quantity of a first material characterized by having a phase change in a predetermined temperature range. The quantity of phase-change material occupies a first volume. One also provides a second quantity of a second material having a negative differential resistance characteristic. This second material may be termed the “filamentary conduction material.” The filamentary conduction material is disposed in contact with the phase-change material and is electrically coupled to the control element. The quantity of filamentary conduction material occupies a second volume. One controls the control element to induce filamentary conduction through the second (filamentary conduction) material. The filamentary conduction occurs in a conduction volume that is a minor fraction of the second volume, such that the filamentary conduction causes the temperature of at least an effective portion of the first (phase-change) material to reach the predetermined temperature range. Thus, a phase change occurs in at least that effective portion of the first (phase change) material. The effective portion also occupies a minor fraction of the first volume.

In the method illustrated by FIG. 1 for programming a non-volatile memory cell of the type having a control element and a storage element, one provides a storage element including a material characterized both by having a phase change in a predetermined temperature range and by having a negative differential resistance characteristic. The material is electrically coupled to the control element. One controls the control element to induce filamentary conduction through the material such that filamentary conduction causes the temperature of at least an effective portion of the material to reach the predetermined temperature range. The filamentary conduction region may provide a localized current-injection source for locally heating the phase-change material.

Thus, a phase change occurs in at least the effective portion of the material. In this method, both the region in which filamentary conduction occurs and the effective portion in which the phase change occurs have volumes that are minor fractions of the volume occupied by the material. In particular, both of the regions have volumes that are less than about one-hundredth of the volume occupied by the material.

It will be understood that in both of the methods described above and illustrated by FIGS. 1 and 2, the lateral position where the filamentary conduction occurs is not necessarily predetermined. Wherever the filamentary conduction first occurs, it forms a filamentary electrode, functionally equivalent to a very small conventional electrode made with a conductor. The position of that filamentary electrode determines the position of the phase-change volume in either method.

Structural Aspects

Another aspect of the invention is represented by a number of novel memory cell structures, described below first in general terms and then in terms of specific structural embodiments. One general embodiment of such a memory cell (illustrated schematically by FIG. 1) has first and second conductive electrodes, each of which has its respective area, and a filamentary conduction medium disposed between the first and second electrodes. The filamentary conduction medium is adapted for filamentary conduction through a filamentary conduction region extending between the first and second electrodes in response to an applied voltage. The filamentary conduction region has a cross-sectional area that is small relative to each of the first and second electrode areas. A control element is connected in series with one of the electrodes. The control element may comprise a tunnel-junction device, which may be a buried tunnel-junction control-element device. The filamentary conduction medium is characterized by having a negative differential resistance. It may also be a phase-change material as defined hereinabove. Alternatively, the filamentary conduction medium may be distinct from the phase-change material. The phase-change material may be disposed between the filamentary conduction medium and one of the electrodes. In particular, the phase-change material and the filamentary conduction medium may be arranged in series between the first and second electrodes. In effect, the filamentary conduction region, once it forms, may extend through both the filamentary conduction medium and the phase-change material. The cross-sectional area of the filamentary conduction region may be made less than one-hundredth of the area of either of the electrodes. The same may be said of cross-sectional area of the phase-changed region.

It will be understood from the previous discussion of relative dimensions that the phase-change material may be adapted to change phase in response to the filamentary conduction, changing phase in a small portion having a cross-sectional area about equal to the small cross-sectional area of the filamentary conduction region. In such a case, for example, the cross-sectional areas of both the filamentary conduction region and the phase-changed-portion of the phase-change material may be made less than one-hundredth of the size of the area of either of the electrodes.

Thus, a general aspect of a memory cell made in accordance with the invention may be represented by a combination of first and second means for connecting the memory cell electrically to a voltage source with means for conducting electric current through a filamentary conduction region of a medium in response to an applied voltage. The medium is disposed between the first and second connecting means, and the filamentary conduction region extends between the first and second connecting means. The filamentary conduction region has a cross-sectional area that is small relative to the area of each of the first and second connecting means.

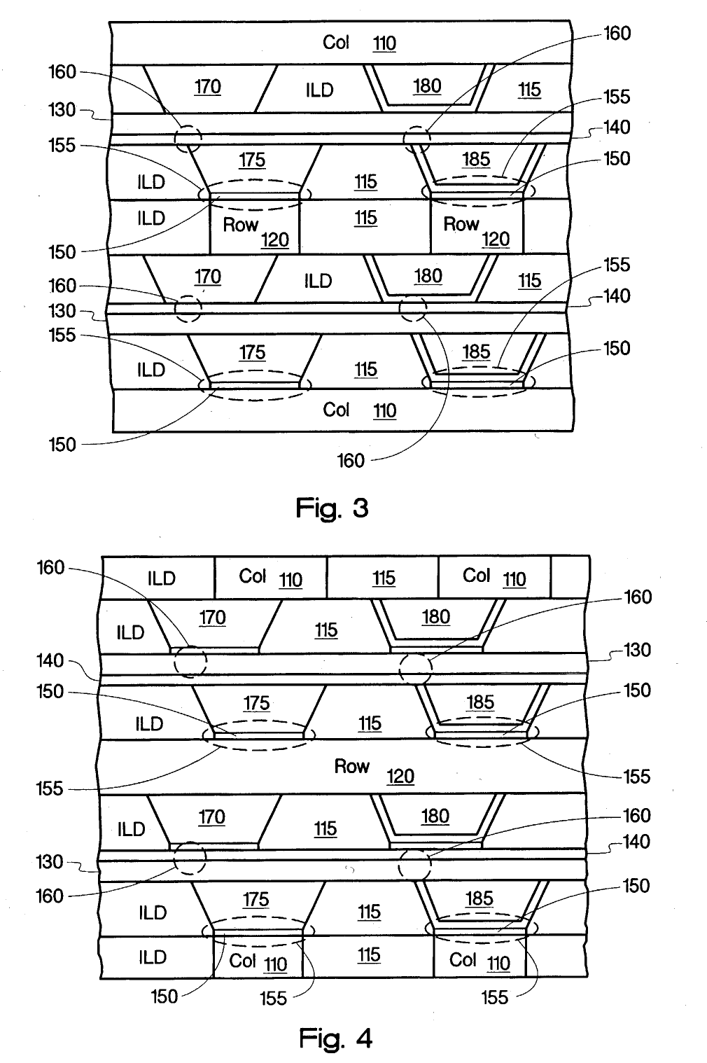

In the remainder of this section, various specific examples of structural embodiments of memories made in accordance with the invention are described in detail, with reference to FIGS. 3-4 and 6-9.

FIGS. 3 and 4 are side-elevation cross-sectional views of a portion of a first embodiment of a crosspoint memory made in accordance with the invention, viewed from different directions orthogonal to each other. In FIG. 3 column conductors 110 extend laterally while row conductors 120 extend perpendicularly to the plane of the drawing. In FIG. 4 row conductor 120 extends laterally while column conductors 110 extend perpendicularly to the plane of the drawing. Layers of interlayer dielectric (ILD) 115 insulate row and column conductors from each other. Resistive heater elements 170 are formed in tub-well openings and are contacted by either row conductors 110 or column conductors 120. Heater elements 175 are also formed in tub-well openings adjacent to heater elements 170. A thin filament conduction layer 140 may be positioned either above or below (or both above and below) heater elements 170 and/or above heater elements 175. In FIGS. 3 and 4 the filament conduction layers 140 are below heater elements 170 and above heater elements 175. A chalcogenide phase-change storage-element layer 130 is in contact with filament conduction layer 140. Control elements 150 formed at the bases of the tub-well openings (indicated by dashed ellipses 155) allow control of each heater element 170 and 175. Control elements 150 may be buried tunnel-junction devices as shown in FIGS. 3 and 4. Dashed circles 160 indicate filament conduction regions. Heater elements 180 and 185 are similar to heater elements 170 and 175, but their tub-well sidewalls are lined with a thin layer of resistive heater material.

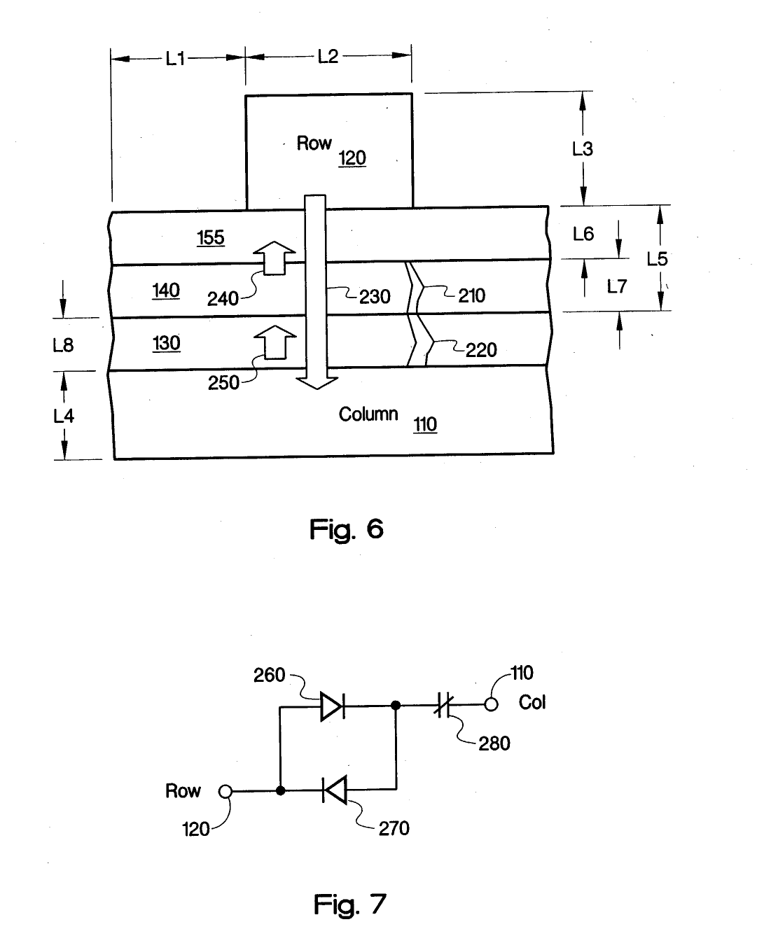

FIG. 6 is a side-elevation cross-sectional view illustrating schematically a portion of a fourth embodiment of a crosspoint memory made in accordance with the invention. By way of example, various typical relative dimensions are shown in FIG. 6 by reference symbols L1, L2, . . . , L8, but FIG. 6 is not drawn to any uniform scale.

In FIG. 6 column conductor 110 extends laterally while row conductor 120 extends perpendicularly to the plane of the drawing. Column conductor 110 and row conductor 120 are formed of conductive materials. Layer 155 is a tunnel-junction control element. Control element layer 155 can be a tunnel-junction oxide that exhibits a relatively high read-state resistance and a relatively low write-state resistance. Arrow 240 represents the direction that control element electrons flow. Layer 140 is the filament conduction layer. Layer 130 is a storage element, which may consist of a phase-change material or a tunnel junction. Arrow 250 represents the direction that storage element electrons flow. A pre-programmed filament 210 provides a conductive path through filament conduction layer 140. When the memory cell is programmed, a second filament 220 is formed. Thus, second filament 220 is a programmed filament. Long arrow 230 represents the direction of current flow.

The dimensions L1, L2, L3, and L4 can all be about equal to each other (for example, about 50-200 nanometers or less). The total thickness L5 of layers 155 and 140 (i.e., L6+L7) can be about one tenth of L1. Some illustrative thicknesses can be L6=about 2-4 nanometers, L7=about 1-2 nanometers for example. The thickness L8 of storage-element layer 130 may be about 2-4 nanometers or less, for example.

FIG. 7 is a schematic diagram of an equivalent circuit corresponding to the embodiment shown in FIG. 6. At a memory cell of the crosspoint memory opposed diodes 260 and 270 together are equivalent to a non-linear tunnel-junction resistance (e.g., control element layer 155 shown in FIG. 6). The resistance of this part of the equivalent circuit can vary from 1 Gigohm with −50 millivolts applied to 10 Megohm with +50 millivolts applied, and only 1 Megohm with +1 volt applied, for example. An antifuse 280 typically will have 10 Megohm OFF resistance (R_{off}) and 500 ohm ON resistance (Rₒₙ), e.g., for an alumina tunnel-junction antifuse. Programmed second filament 220, shown in FIG. 6, may have such resistance values before and after filament formation.

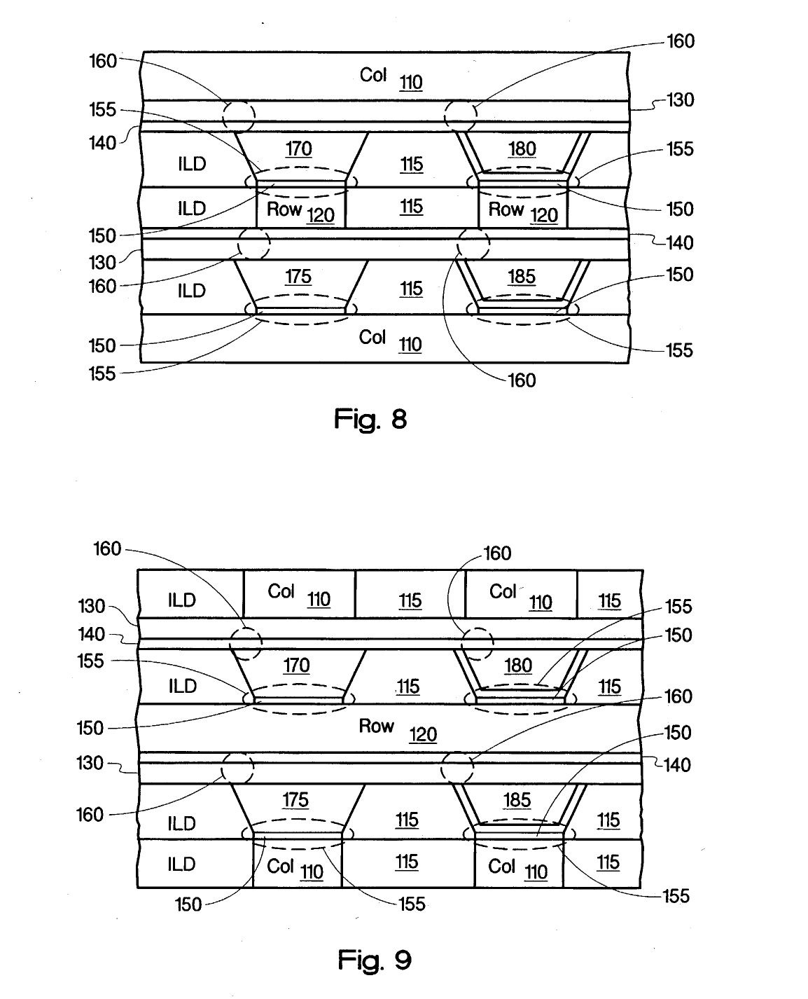

FIGS. 8 and 9 are side-elevation cross-sectional views of a portion of a memory embodiment as illustrated schematically in FIG. 6, viewed from two directions orthogonal to each other. As illustrated by FIGS. 8 and 9, this memory structure embodiment is simpler than the embodiments described above. In FIG. 8 column conductors 110 extend laterally while row conductors 120 extend perpendicularly to the plane of the drawing. In FIG. 9 row conductor 120 extends laterally while column conductors 110 extend perpendicularly to the plane of the drawing. Again, layers of interlayer dielectric (ILD) 115 insulate row and column conductors from each other. Heater elements 170 and 175 are formed in tub-well openings and are contacted by either row conductors 110 or column conductors 120. Here the heater elements 170 and 175 may comprise resistive heater material. In FIGS. 8 and 9 the thin filament conduction layers 140 are positioned above heater elements 170 and 175. A chalcogenide phase-change storage-element layer 130 is in contact with filament conduction layer 140. Control elements 150 formed at the bases of the tub-well openings (indicated by dashed ellipses 155) allow control of each heater element 170 or 175. Control elements 150 are formed by thin tunnel junctions: for example, thin films of aluminum oxide (Al₂O₃). Control elements 150 may be buried tunnel-junction devices, as shown in FIGS. 8 and 9. Dashed circles 160 indicate the general region where filament formation occurs. Heater elements 180 and 185 are similar to heater elements 170 and 175; but their tub-well sidewalls are lined with a thin layer of resistive heater material. Titanium, tungsten, and their alloys are suitable resistive materials.

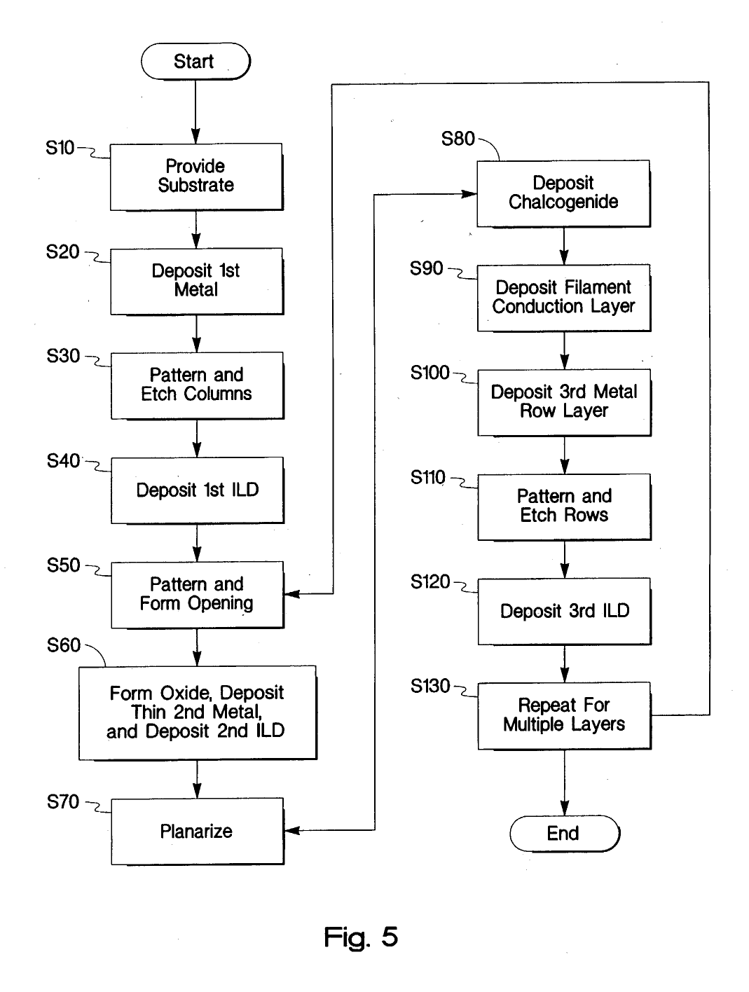

Memories like those of FIGS. 3-4 and 6-9 are fabricated by methods such as the method embodiment that is illustrated in the flow chart of FIG. 5 and described in more detail below.

Fabrication

Overall fabrication methods suitable for making the present invention are described in commonly-assigned U.S. patent application Ser. No. 10/001,740 filed Oct. 31, 2001 and Ser. No. 10/116,213 filed Apr. 2, 2002, the entire disclosure of each of which is incorporated herein by reference.

FIG. 5 is a flow chart illustrating an embodiment of a specific method for fabricating a memory in accordance with the invention. Various steps of the method are denoted by reference numerals S10, . . . , S130. As shown in FIG. 5, the method begins with the step of providing a substrate (S10). A first metal layer is deposited upon the substrate (S20). The first metal layer is patterned and etched (S30). A first inter-layer dielectric (ILD) is deposited (S40) over the first metal layer. An opening though the first ILD layer is patterned and etched (S50), exposing a portion of the first metal layer. A thin oxide layer is formed on the exposed portion of the first metal layer, a thin second metal layer is deposited, and a second inter-layer dielectric (ILD) layer is deposited (S60). Thus, a tunnel junction formed between the first and second metal layers in step S60 is a buried tunnel junction. The resultant surface is planarized (S70). Conventional chemical-mechanical polishing (CMP) may be employed for planarizing the surface. A layer of a phase-change material such as chalcogenide is deposited (S80). A layer of a filamentary conduction medium is deposited (S90). A third metal layer is deposited (S100). The third metal layer is patterned and etched (S110), e.g., to form row conductors. If a third inter-layer dielectric (ILD) is needed, it is deposited (S120). If a dielectric layer is not needed, step S120 is omitted. The third ILD may be needed to provide a substrate for additional levels of memory. The process is repeated (S130) as many times as necessary to form multiple layers of memory.

It will be understood that for the purpose of describing the fabrication the designation of a specific order of forming column lines and row lines is arbitrary. Thus, for example, the step S30 of patterning and etching the first metal layer may be performed to define column lines as described above or may be performed to define row lines instead. Similarly, step S110 of patterning and etching the third metal layer may be performed to define row lines or column lines. By this process a single memory cell may be made, or a number of memory cells may be made simultaneously to form a layer of memory. With repetition (step S130), steps S10-S120 are performed for the first layer, and steps S20-S120 are repeated for each successive subsequent layer until the last. Those skilled in the art will recognize that the last ILD deposition in the last layer may be omitted in some applications, or the ILD layer may be processed further to provide vias and/or lead-bonding pads or equivalents.

Thus, another aspect of the invention is a method for using a non-volatile memory cell of the type having a control element and a storage element in a cross-point memory structure of the type having column and row lines. This method includes connecting an electrode to each column line, connecting another electrode to each row line, placing a phase-change material and a filamentary conduction medium between each pair of the electrodes to form each storage element, and controlling each control element to selectively change the phase of a portion of the phase-change material at a selected row-column combination by inducing filamentary conduction through the filamentary conduction medium associated with the corresponding electrodes. In such a method, the phase-change material can comprise a chalcogenide. Also, the filamentary conduction medium can comprise a semiconductor. The phase-change material and the filamentary conduction medium can be identical. The control element can comprise a buried tunnel-junction device. In such a method, the filamentary conduction region can be pre-programmed.

Those skilled in the art will recognize that an integrated circuit or another electronic device may be made comprising a number of memory cells according to the present invention. Similarly, a mass storage device comprising a number of such memory cells may be made. A substrate carrying electronics may advantageously be made using methods and the memory cell structure according to the present invention.

### INDUSTRIAL APPLICABILITY

The methods described and the structures made according to the present invention may be used in a memory cell, a memory comprised of a number of such cells (including a multi-layer memory), a mass storage device, an integrated circuit, a substrate carrying electronics, or another electronic device, and applied to a multitude of known or novel uses for memory.

Although the foregoing has been a description and illustration of specific embodiments of the invention, various modifications and changes can be made thereto by persons skilled in the art without departing from the scope and spirit of the invention as defined by the claims. For example, various phase-change materials may be substituted for the chalcogenides and other phase-change materials described. Various other materials may be substituted for the filamentary conduction materials described. The order in which process steps are performed may be varied to some extent.

What is claimed is:

1. A method for programming a non-volatile memory cell of the type having a control element and a storage element, said method comprising the steps of:
a) providing a storage element including a first material characterized by having a phase change in a predetermined temperature range;
b) providing a second material having a negative differential resistance characteristic, said second material being in contact with said first material and being electrically coupled to said control element; and
c) controlling said control element to induce filamentary conduction through said second material such that said filamentary conduction causes the temperature of at least a portion of said first material to reach said predetermined temperature range, whereby a phase change occurs in at least said portion of said first material.

2. The method of claim 1 wherein said first material and said second material are co-extensive.

3. The method of claim 1 wherein said first material and said second material are identical.

4. The method of claim 1 wherein said first material and said second material are different.

5. The method of claim 1 wherein said first material and said second material are electrically connected in series.

6. The method of claim 1 wherein said first material comprises a semiconductor.

7. The method of claim 1 wherein said first material comprises a chalcogenide.

8. The method of claim 1 wherein said second material has a positive thermal coefficient of resistance.

9. The method of claim 1 wherein said second material comprises a semiconductor.

10. The method of claim 1 wherein said second material comprises a chalcogenide.

11. The method of claim 1 wherein said second material comprises a substance selected from the list consisting of a chalcogenide, silicon, germanium, gallium arsenide, gallium nitride, silicon nitride, silicon dioxide, aluminum oxide, and alloys, compounds, combinations, and mixtures thereof.

12. The method of claim 1, wherein said filamentary conduction occurs in a region of said second material, said region having a diameter of less than about ten nanometers.

13. The method of claim 1, wherein said filamentary conduction occurs in a region of said second material, said region of said second material having a cross-sectional area of less than about eighty square nanometers.

14. The method of claim 1, wherein said filamentary conduction occurs in a region of said second material, wherein said region of said second material provides a localized source for injection of current for locally heating said first material.

15. The method of claim 1, wherein said filamentary conduction is induced by impact ionization.

16. The method of claim 1, wherein said filamentary conduction is induced by avalanche injection.

17. The method of claim 1, wherein said filamentary conduction is induced by charge-enhanced tunneling.

18. The method of claim 1, wherein said portion of said first material in which said phase change occurs has a diameter of less than about ten nanometers.

19. The method of claim 1, wherein said portion of said first material in which said phase change occurs has a cross-sectional area of less than about eighty square nanometers.

20. The method of claim 1, wherein said control element has a control element electrode having an area, and wherein said portion of said first material in which said phase change occurs has a cross-sectional area of less than said area of said control element electrode.

21. The method of claim 20, wherein said portion of said first material in which said phase change occurs has a cross-sectional area that is a minor fraction of said area of said control element electrode.

22. The method of claim 20, wherein said portion of said first material in which said phase change occurs has a cross-sectional area that is less than one-hundredth of said area of said control element electrode.

23. The method of claim 1, wherein said storage element has a storage element electrode having a storage-element-electrode area, and wherein said portion of said first material in which said phase change occurs has a cross-sectional area of less than said storage-element-electrode area.

24. The method of claim 23, wherein said portion of said first material in which said phase change occurs has a cross-sectional area that is a minor fraction of said storage-element-electrode area.

25. The method of claim 23, wherein said portion of said first material in which said phase change occurs has a cross-sectional area that is less than about one-hundredth of said storage-element-electrode area.

26. The method of claim 1, wherein said control element has a control element electrode having a control-element-electrode area, and wherein said filamentary conduction occurs in a region of said second material, said region of said second material having a cross-sectional area of less than said control-element-electrode area.

27. The method of claim 26, wherein said region of said second material in which said filamentary conduction occurs has a cross-sectional area that is a minor fraction of said control-element-electrode area.

28. The method of claim 26, wherein said region of said second material in which said filamentary conduction occurs has a cross-sectional area that is less than about one-hundredth of said control-element-electrode area.

29. The method of claim 1, wherein said storage element has a storage element electrode having a storage-element-electrode area, and wherein said filamentary conduction occurs in a region of said second material, said region of said second material having a cross-sectional area of less than said storage-element-electrode area.

30. The method of claim 29, wherein said region of said second material in which said filamentary conduction occurs has a cross-sectional area that is a minor fraction of said storage-element-electrode area.

31. The method of claim 29, wherein said region of said second material in which said filamentary conduction occurs has a cross-sectional area that is less than about one-hundredth of said storage-element-electrode area.

32. A method for programming a non-volatile memory cell of the type having a control element and a storage element, said method comprising the steps of:
a) providing a storage element including a first quantity of a first material characterized by having a phase change in a predetermined temperature range, said first quantity occupying a first volume;
b) providing a second quantity of a second material having a negative differential resistance characteristic, said second material being in contact with said first material and being electrically coupled to said control element, and said second quantity occupying a second volume; and
c) controlling said control element to induce filamentary conduction through said second material, said filamentary conduction occurring in a conduction volume that is a minor fraction of said second volume, such that said filamentary conduction causes the temperature of at least an effective portion of said first material to reach said predetermined temperature range, whereby a phase change occurs in at least said effective portion of said first material, said effective portion occupying a minor fraction of said first volume.

33. A method for programming a non-volatile memory cell of the type having a control element and a storage element, said method comprising the steps of:
a) providing a storage element including a material characterized by having a phase change in a predetermined temperature range and by having a negative differential resistance characteristic, said material being electrically coupled to said control element; and
b) controlling said control element to induce filamentary conduction through said material such that said filamentary conduction causes the temperature of at least an effective portion of said material to reach said predetermined temperature range, whereby a phase change occurs in at least said effective portion of said material.

34. The method of claim 33, wherein said material occupies a volume and said filamentary conduction occurs in a region of said volume, and wherein each of said region in which said filamentary conduction occurs and said effective portion of said material in which said phase change occurs has a volume that is a minor fraction of the volume occupied by said material.

35. The method of claim 34, wherein each of said region in which said filamentary conduction occurs and said effective portion of said material in which said phase change occurs has a volume that is less than about one-hundredth of the volume occupied by said material.

36. A memory cell comprising:
a) a first electrode having a first electrode area;
b) a second electrode having a second electrode area;
c) a filamentary conduction medium disposed between said first and second electrodes, said filamentary conduction medium being adapted for filamentary conduction through a filamentary conduction region extending between said first and second electrodes in response to an applied voltage, said filamentary conduction region having a cross-sectional area that is small relative to each of said first and second electrode areas.

37. The memory cell of claim 36, further comprising a control element connected in series with one of said first and second electrodes.

38. The memory cell of claim 37, wherein said control element comprises a tunnel-junction device.

39. The memory cell of claim 38, wherein said tunnel-junction device is buried.

40. The memory cell of claim 36, wherein said filamentary conduction medium is characterized by a negative differential resistance.

41. The memory cell of claim 36, wherein said filamentary conduction medium comprises a phase-change material.

42. The memory cell of claim 36, further comprising a phase-change material.

43. The memory cell of claim 42, wherein said filamentary conduction medium is distinct from said phase-change material.

44. The memory cell of claim 42, wherein said phase-change material is disposed between said filamentary conduction medium and one of said first and second electrodes.

45. The memory cell of claim 42, wherein said phase-change material and said filamentary conduction medium are arranged in series between said first and second electrodes.

46. The memory cell of claim 42, wherein said filamentary conduction region extends through said filamentary conduction medium and said phase-change material.

47. The memory cell of claim 42, wherein said phase-change material is adapted to change phase in a portion thereof having a cross-sectional area about equal to said cross-sectional area of said filamentary conduction region, in response to said filamentary conduction.

48. The memory cell of claim 47, wherein each of
a) said cross-sectional area of said filamentary conduction region and
b) said cross-sectional area of said portion of said phase-change material is less than one-hundredth of each of said first and second electrode areas.

49. The memory cell of claim 42, wherein said cross-sectional area of said filamentary conduction region is less than one-hundredth of each of said first and second electrode areas.

50. The memory cell of claim 36, wherein said cross-sectional area of said filamentary conduction region is less than about one-hundredth of each of said first and second electrode areas.

51. An integrated circuit comprising the memory cell of claim 36.

52. A mass storage device comprising a plurality of memory cells of claim 36.

53. An electronic device comprising the memory cell of claim 36.

54. A substrate with electronics, comprising the memory cell of claim 36.

55. A memory cell comprising in combination:
a) first means for connecting said memory cell electrically to a voltage source;
b) second means for connecting said memory cell electrically to the voltage source; and
c) means for conducting electric current through a filamentary conduction region of a medium in response to an applied voltage, said medium being disposed between said first and second connecting means, and said filamentary conduction region extending between said first and second connecting means, said filamentary conduction region having a cross-sectional area that is small relative to each of said first and second connecting means.

56. A method for fabricating a memory cell, said method comprising the steps of:
a) providing a substrate;
b) depositing a first metal layer upon the substrate;
c) patterning and etching the first metal layer;
d) depositing a first inter-layer dielectric (ILD) layer over the first metal layer;
e) patterning and etching an opening though the first ILD layer, exposing a portion of the first metal layer;
f) forming a thin oxide layer on said exposed portion of the first metal layer;
g) depositing a thin second metal layer;
h) depositing a second inter-layer dielectric (ILD) layer;
i) planarizing the resultant surface;
j) depositing a phase-change material layer;
k) depositing a layer of a filamentary conduction medium;
l) depositing a third metal layer; and
m) patterning and etching the third metal layer.

57. The fabrication method of claim 56, further comprising the step of:
n) depositing a third dielectric layer if needed.

58. The fabrication method of claim 56, wherein the step c) of patterning and etching the first metal layer is performed to define column lines.

59. The fabrication method of claim 56, wherein the step m) of patterning and etching the third metal layer is performed to define row lines.

60. The fabrication method of claim 56, wherein the step c) of patterning and etching the first metal layer is performed to define row lines.

61. The fabrication method of claim 56, wherein the step m) of patterning and etching the third metal layer is performed to define column lines.

62. A memory cell made by the process of claim 56.

63. A method for fabricating a memory, comprising the steps of:
performing steps a) through n) of claim 57 for a first layer of a set of multiple layers; and
repeating steps b) through n) of claim 57 for each successive layer.

64. A memory made by the method of claim 63.

65. A mass storage device comprising the memory of claim 64.

66. An integrated circuit comprising the memory of claim 64.

67. An electronic device comprising the memory of claim 64.

68. A substrate carrying electronics comprising the memory of claim 64.

69. A method for using a non-volatile memory cell of the type having a control element and a storage element in a cross-point memory structure of the type having column and row lines, said method comprising the steps of:
a) connecting a first electrode to each column line;
b) connecting a second electrode to each row line;
c) disposing a phase-change material and a filamentary conduction medium between each pair of the first and second electrodes to form each storage element;
d) controlling each control element to selectively change the phase of a portion of the phase-change material at a selected row-column combination by inducing filamentary conduction through the filamentary conduction medium associated with the corresponding first and second electrodes.

70. The method of claim 69, wherein the phase-change material comprises a chalcogenide.

71. The method of claim 69, wherein the filamentary conduction medium comprises a semiconductor.

72. The method of claim 69, wherein the filamentary conduction medium comprises an insulator before filamentary conduction is induced.

73. The method of claim 69, wherein the phase-change material and the filamentary conduction medium are identical.

74. The method of claim 69, wherein the control element comprises a buried tunnel-junction device.
